(19) United States
(12) Patent Application Publication
(10) Pub. No.: US 2025/0056846 A1
(43) Pub. Date: Feb. 13, 2025

(54) TRANSISTOR DEVICE AND METHOD

(71) Applicant: Infineon Technologies Austria AG, Villach (AT)

(72) Inventors: Hans Weber, Villach (AT); Björn Fischer, München (DE); David Kammerlander, Villach (AT); Dan Horia Popescu, München (DE)

(21) Appl. No.: 18/794,509

(22) Filed: Aug. 5, 2024

(30) Foreign Application Priority Data
Aug. 10, 2023 (DE) 102023121421.7
Sep. 5, 2023 (DE) 102023208539.9

(51) Int. Cl. H01L 29/06; H01L 29/08; H01L 29/417; H01L 29/66; H01L 29/78

(52) U.S. Cl. CPC H01L 29/0607; H01L 29/086; H01L 29/41775; H01L 29/66734; H01L 29/7813

(57) ABSTRACT

A transistor device and a method for producing source regions of a transistor device are disclosed. The transistor device includes a semiconductor body with a plurality of mesa regions and a plurality of transistor cells each formed in a respective one of the mesa regions. Each transistor cell includes: a source region of a first doping type; a gate region of a second doping type complementary to the first doping type and spaced apart from the source region; a channel region of the first doping type; and a transition region different from the source region and the gate region. The transition region is arranged between the source region and the gate region and adjoins both the source region and the gate region.

### TECHNICAL FIELD

This disclosure relates in general to a transistor device, in particular a JFET (Junction Field-Effect Transistor).

### BACKGROUND

A JFET is a normally-on transistor device that may include a plurality transistor that are each formed in a respective one of a plurality of mesa regions and that each include a source region of a first doping type, and a gate region of a second doping type complementary to the first doping type. The JFET can be switched on or off by applying a suitable drive voltage between the source and gate regions.

There is a need for a JFET with a low leakage current.

### SUMMARY

One example relates to a transistor device. The transistor device includes a semiconductor body including a plurality of mesa regions, and a plurality of transistor cells each formed in a respective one of the plurality of mesa regions. Each transistor cell includes a source region of a first doping type, a gate region of a second doping type complementary to the first doping type and spaced apart from the source region, a channel region of the first doping type, and a transition region different from the source region and the gate region, wherein the transition region is arranged between the source region and the gate region and adjoins both the source region and the gate region.

Another example relates to a method. The method includes forming trenches in a first surface of a semiconductor body, so that mesa regions of the semiconductor body are formed, each mesa region being located between neighboring trenches. Forming the trenches includes an etching process using an etch mask formed above the first surface, forming sacrificial plugs in the trenches such that the sacrificial plugs fill the trenches and, in a vertical direction of the semiconductor, extend beyond the first surface, removing the etch mask, so that sidewalls of the sacrificial plugs are uncovered, forming spacers on the sidewalls of the sacrificial plugs, and forming source regions of a first doping type in the mesa regions. Forming the source regions includes implanting dopant atoms of the first doping type into the first surface using the sacrificial plugs and the spacers as an implantation mask.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 illustrates one example of a transistor device that includes a plurality of transistor cells each arranged in a respective one of a plurality of mesa regions of a semiconductor body and each including a source region, a gate region, a channel region, and a transition region arranged between the source region and the gate region;

FIG. 2 illustrates one example of the transistor device in which the mesa regions are elongated regions;

FIG. 3 illustrates one example of the transistor device in which the mesa regions are pile-shaped regions;

FIG. 4 schematically illustrates one example of a transistor device that further includes a drift region and a drain region adjoining the drift region;

FIG. 5 illustrates one example of a channel region of the transistor cells;

FIGS. 6-11 show detailed views of one section of a transistor cell to illustrate different examples of the transition region;

FIG. 12 illustrates one example of a transistor device that further includes gate electrodes and a source electrode;

FIG. 13 illustrates a top view of the overall transistor device according to one example;

FIGS. 14A-14E illustrate one example of a method for forming the source regions;

FIG. 15 illustrates one example of a method for forming the gate regions;

FIG. 16 illustrates one example of a method for forming portions of the channel regions;

FIG. 17 illustrates one example of a method for forming portions of the channel regions and for forming first regions of the transition regions using the same implantation processes;

FIGS. 18A-18C illustrate another example of a method for forming first regions of the transition regions; and

FIG. 19 illustrates one example of a transition region formed by a combination of the method according to FIG. 15 and one of the methods according to FIGS. 17 and 18A-18C.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

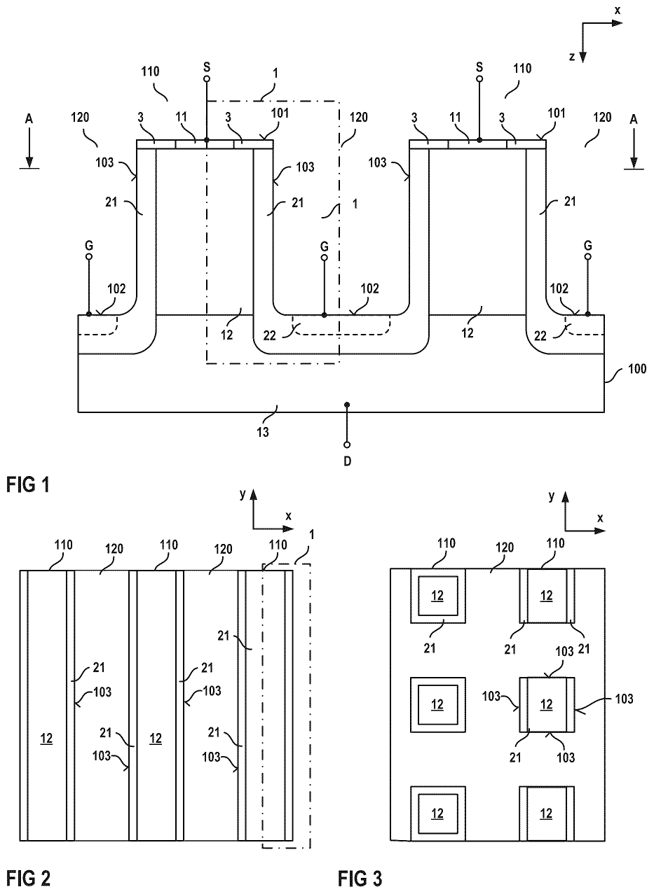

FIG. 1 schematically illustrates one example of a transistor device implemented as a JFET. More specifically, FIG. 1 illustrates one section of a semiconductor body 100 in which active device regions of the JFET are integrated. The semiconductor body 100 includes monocrystalline silicon (Si) or monocrystalline silicon carbide (SiC), for example.

Referring to FIG. 1, the semiconductor body 100 includes a plurality of mesa regions 110 and a plurality of trenches 120. Each of the trenches extends from a first surface 101 of the semiconductor body 100 into the semiconductor body 100. Each mesa region 110 is defined by trenches 120 adjoining the mesa region 110 and is arranged between neighboring ones of the plurality of trenches 120.

The transistor device further includes a plurality of transistor cells 1, which may also be referred to as control cells or head structure cells of the transistor device. Each transistor cell 1 is formed in a respective one of the plurality of mesa regions 110. Furthermore, each transistor cell 1 includes a source region 11 of a first doping type, a gate region 21 of a second doping type complementary to the first doping type and spaced apart from the source region 11, a channel region 12 of the first doping type, and a transition region 3. The transition region 3 is different from the source region 11 and the gate region 21, is arranged between the source region 11 and the gate region 21, and adjoins both the source region 11 and the gate region 21. The transition region 3 may also be referred to as and/or may have the function of a voltage absorbing region or leakage current reducing region or source-gate drift region. Details on the function and the implementation of the transition region 3 are explained herein further below.

According to one example, the transition region 3 being different from the source region 11 and the gate region 21 includes that (a) at least one of the doping type and the doping concentration of the transition region 3 is different from the respective doping type and the doping concentration of the source region 11, and (b) at least one of the doping type and the doping concentration of the transition region 3 is different from the respective doping type and the doping concentration of the gate region 21. Details of the transition region 3 and different examples for implementing the transition region 3 are explained herein further below.

Unless stated otherwise, as used herein, the doping concentration of a certain region is the peak (or maximum) doping concentration of the respective region. Thus, the doping concentration of the transition region 3 being different from the doping concentration of the source region 11 or the gate region 21 includes that the peak doping concentration of the transition region 3 is different from the peak doping concentration of the source region 11 or the gate region 21.

More specifically, the peak doping concentration denotes the effective peak doping concentration. In a region that includes dopant atoms of the first doping type and dopant atoms of the second doping type, the doping type of the region is given by the doping type of those dopant atoms that prevail in the respective region. The effective peak doping concentration is given by the peak doping concentration of the dopant atoms that prevail minus the peak doping concentration of the dopant atoms that do not prevail. Assuming that the dopant atoms of the first doping type prevail, the effective doping is a first type doping and the peak doping concentration is given by the peak doping concentration of the first type dopant atoms minus the peak doping concentration of the second type dopant atoms.

According to one example illustrated in FIG. 1, the transistor device further includes a drift region 13 of the first doping type that adjoins the channel regions 12 of the plurality of transistor cells 1 in a vertical direction z of the semiconductor body 100. The “vertical direction z” is a direction that is essentially perpendicular to the first surface 101 of the semiconductor body 100.

The source regions 11 of the transistor cells 1 are connected to a source node S of the transistor device, the gate regions 21 are connected to a gate node G of the transistor device, and the drift region 13 is connected to a drain node D of the transistor device. Connections between the source regions 11 and the source node S, connections between the gate regions 21 and the gate node G, and a connection between the drift region 13 and the drain node D are only schematically illustrated in FIG. 1. Examples for implementing these connections are explained herein further below.

Referring to FIG. 1, each of the mesa regions 110 includes a top surface, which is a portion of the first surface 101 of the semiconductor body 100, and sidewalls 103. The sidewalls 103 of one mesa region 120, at the same time, are sidewalls of the trenches 120 forming (defining) the respective mesa region 110. Each of the trenches 120 further includes a bottom 102, which is surface of the trench 120 that is spaced apart from the top surfaces 101 of the mesa regions 110 in the vertical direction z.

According to one example, the source region 11 of each transistor cell adjoins the top surface 101 of the mesa region 110 in which the respective transistor cell 1 is integrated. Furthermore, the gate region 21 of each transistor cell 1, adjoins a respective sidewall 103 of the mesa region 110 in which the respective transistor cell 1 is integrated. Just for the purpose of illustration and explanation it is assumed that the gate region 21 of one transistor cell 1 adjoins exactly one of the sidewalls 103 of one mesa regions. In this example, two or more transistor cells 1 can be formed within one mesa region 110, wherein the source regions 11 of the two or more transistor cells can be formed by one contiguous doped region of the first doping type.

In the example illustrated in FIG. 1, gate regions 21 of two transistor cells 1 are formed along opposite sidewalls 103 of one mesa region 110. In this example, the channel regions 12 of the two transistor cells 1 are formed by one contiguous doped region of the first doping type. Implementing the transistor cells in this way, however, is only one example. It is also possible to implement the transistor device such that one mesa region 110 includes the gate region 21 and the corresponding channel region 12 of only one transistor cell, so that along only one sidewall 103 of the mesa region 110 a gate region 21 is formed and the channel region 12 adjoins the opposite sidewall 103 of the mesa region 110.

In the example illustrated in FIG. 1, the mesa regions 110 are spaced apart from each other in a first lateral direction x of the semiconductor body 100. In a second lateral direction y perpendicular to the first lateral direction x, the mesa regions 110 may be implemented in various ways.

According to one example illustrated in FIG. 2, at least some or all of the mesa regions 110 are elongated in the second lateral direction y. For example, at least some or all of the mesa regions 110 are stripe-shaped. The trenches 120 adjoining the elongated mesa regions 110 may also be elongated, e.g. stripe-shaped.

According to another example illustrated in FIG. 3, the mesa regions 110 are pile-shaped. The mesa regions 110, for instance, may be surrounded by at least three (e.g., four or six) trenches 120 in the horizontal plane. In the example illustrated in FIG. 3, a cross-section of the mesa regions 110 in the horizontal plane parallel to the first surface 101 is rectangular. This, however, is only an example. Other types of cross-sections (e.g., hexagonal, elliptical, in particular circular, or triangular) are possible as well. A gate region 21 may be formed along each of the sidewalls 103 of each mesa region 110. This is illustrated on the left side in FIG. 3. According to another example, gate regions are formed only along two opposite sidewalls 103. This is illustrated on the right side in FIG. 3.

The transistor device can be operated in an on-state or an off-state. In the on-state, there is a conducting channel in each of the channel regions 12, so that a current can flow in the transistor device between the drain node D and the source node S when a corresponding voltage is applied between the drain and source nodes D, S. In the off-state, the channel regions 12 are depleted of charge carriers, so that there are no conducting channels between the source regions 11 and the drift region 13.

The operating state (on-state or off-state) of the transistor device can be controlled by suitably selecting a voltage level of a drive voltage (gate-source voltage) applied between the gate node G and the source node S. The channel region 12 of each transistor cell 1 adjoins the gate region 21 of the respective transistor cell 1 and is electrically coupled to the source region 11, either directly or via the transition region 3. The latter may include that the channel region 12 adjoins the source region 11 or is coupled to the source region 11 through the transition region 3. Examples for coupling the channel region 12 to the source region 11 through the transition region 3 are explained herein further below.

As the channel region 12 of each transistor cell 1 adjoins the gate region 21 and is coupled to the source region 11, a space charge region (depletion region) in the channel region 12 can be controlled by the gate-source voltage. In the off-state of the transistor device, the gate-source voltage is such that a space charge region (depletion region), beginning at a PN junction formed between the channel region 12 and the gate region 21, expands into the channel region 12 such that the channel region 12 is entirely depleted of charge carriers.

A voltage level of the gate source voltage that switches off the transistor device is referred to as threshold voltage in the following. The threshold voltage, inter alia, is dependent on a dopant dose in the channel region 12 in a direction perpendicular to the PN junction formed between the channel region 12 and the gate region 21, and is dependent on a dopant profile of dopant atoms in the channel region in the direction perpendicular to the PN junction. The “dopant dose” is the integral of the doping concentration of the channel region 21 in the direction perpendicular to the PN junction. According to one example, the magnitude of the threshold voltage is between 5 V and 20 V

The polarity of the threshold voltage is dependent on the conductivity type of the transistor device. According to one example, the transistor device is an N-type transistor device. In this example, the first doping type, which is the doping type of the source and channel regions 11, 12 and the drift region 13 is an N-type, and the second doping type, which is the doping type of the gate regions 21 is a P-type. According to another example, the transistor device is a P-type transistor device. In this example, the first doping type, which is the doping type of the source and channel regions 11, 12 and the drift region is a P-type, and the second doping type, which is the doping type of the gate regions 21 is an N-type. In an N-type transistor device, the threshold voltage is negative. In a P-type transistor device, the threshold voltage is positive.

Referring to the above, the sidewall 103 of each mesa region 110, at the same time, may be the sidewall of the trench 120 adjoining the mesa region 110. According to one example illustrated in FIG. 1, gate regions 21 of neighboring transistor cells 1 formed along opposite sidewalls of each trench 120 extend into the drift region 13 and along the bottom 102 of the trench 120. The gate regions 21 of the neighboring transistor cells 1 adjoin each other below the trench bottom 102 and form a PN junction with the drift region 13. Thus, in the off-state of the transistor device, depletion regions (space charge regions) do not only expand in the channel regions 12 of the transistor cells 1, but also expand in the drift regions 13 beginning at the PN junctions between the gate regions 21 and the drift regions 13. According to one example, the section of the gate regions 21 formed below the trench bottom includes a higher doped region 22 that has a doping concentration that is higher than the doping concentration of the remainder of the gate regions 21.

Referring to the above, the semiconductor body 100 includes monocrystalline Si or monocrystalline SiC, for example. While the basic topology of the transistor device is independent on the type of semiconductor material of the semiconductor body 100, doping concentrations of the individual active device regions and dimensions may be different when implementing the transistor device based on Si or based on SiC. In the following, unless stated otherwise, absolute values of doping concentrations and dimensions relate to a transistor device implemented based on a SiC semiconductor body 100.

According to one example, the doping concentration of the gate regions 21 is higher than 1E18 cm⁻³. The doping concentration of the gate regions 21 is selected from between 1E18 cm⁻³ and 1E19 cm⁻³, for example. According to one example, the doping concentration of the source regions 11 is higher than 1E19 cm⁻³. The doping concentration of the source regions 11 is selected from between 1E19 cm⁻³ and 1E21 cm⁻³, for example.

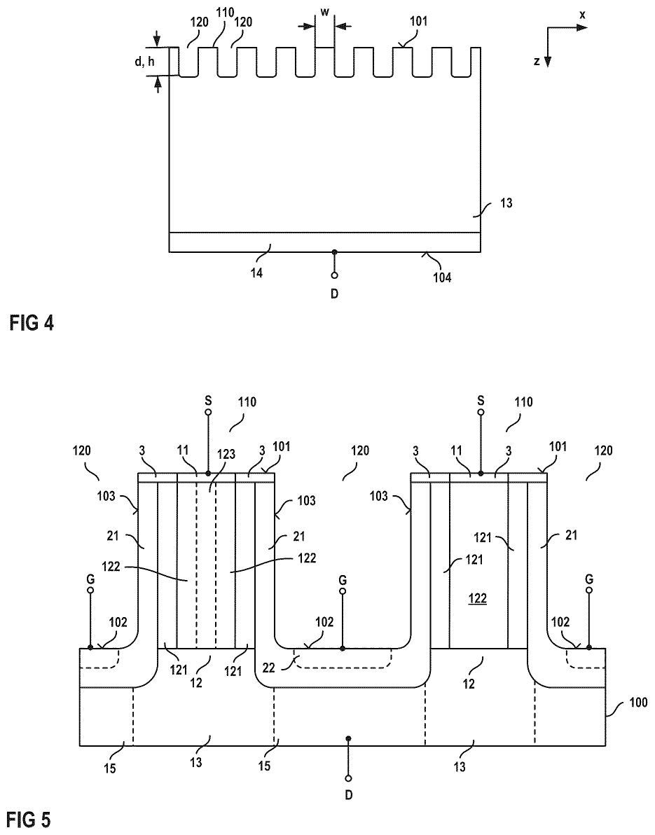

According to one example, the drift region 13 is connected to the drain node D via a drain region 14. This is illustrated in FIG. 4, which shows a vertical cross-sectional view of one section of the semiconductor body 100. Details of the transistor cells 1 are not illustrated in FIG. 2.

Referring to FIG. 4, the drain region 14 may form a second surface 104 opposite the first surface 101 of the semiconductor body 100. In this example, the drain node D may be formed by a metallization on top of the second surface 104. This, however, is only an example. According to another example (not illustrated) the drain region 14 is a buried layer within the semiconductor body 100 and, at a position spaced apart from the position illustrated in FIG. 2 and spaced apart from the transistor cells 1, is connected to a drain node at the first surface 101 of the semiconductor body 100.

The drain region 14 is of the first doping type, so that the drain region 14 is of the same doping type as the drift region 13, and has a higher doping concentration than the drift region 13. According to one example, the doping concentration of the drift region 13 is selected from between 1E14 cm⁻³ and 1E17 cm⁻³. The doping concentration of the drain region 14 is at least 1E18 cm⁻³, for example.

The voltage blocking capability of the transistor device, which is the maximum voltage the transistor device can withstand in the off-state, is, inter alia, dependent on a length of the drift region 13. The length of the drift region 13 is essentially the dimension of the drift region 13 in the vertical direction z. According to one example, the voltage blocking capability of the transistor device is between 600 V and 1200 V and the length of the drift region is between 3 and 8 micrometers.

Mesa widths w, which are dimensions of the mesa regions 110 in the first lateral direction x are between 0.3 micrometers and 2 micrometers, for example. Trench depths d, which are dimensions of the trenches 120 in the vertical direction z are selected from between 0.5 micrometers and 3 micrometers, for example. The trench depths d essentially equally heights h of the mesa regions 110.

According to one example, the channel region 12 is an essentially homogeneously doped semiconductor region.

According to another example illustrated in FIG. 5, the channel region 12 of each transistor cell 1 includes two differently doped regions, a first region 121 adjoining the gate region 21, and a second region 122 adjoining the first region 121 and separated from the gate region 21 by the first region 121. Each of the first and second regions 121, 122 is a doped region of the first doping type. The first region 121 has a higher doping concentration than the second region 122. According to one example, the doping concentration of the first region 121 is at least 5 times or at least 10 times the doping concentration of the second region 122. According to one example, the doping concentration of the first region 121 of the channel region 12 is selected from between 1E17 cm⁻³ and 1E18 cm⁻³.

According to one example, a third region 123 is arranged in the center of each mesa region 120 between the second regions 122 of two transistor cells 1 formed in the same mesa region 120. The doping concentration of the third region 123 is less than 10⁻¹ (0.1) times the doping concentration of the first region 121 and is selected from between 0.01 times and 0.1 times the doping concentration of the first region 121, for example. The third region 123 is a doped region of the first doping type.

According to one example illustrated in dashed lines in FIG. 5, the transistor device is a superjunction transistor device. In this example, the transistor device includes a plurality of compensation regions 15 of the second doping type, wherein each of the compensation regions 15 adjoins a respective one of the gate regions 21 and adjoins a respective portion of the drift region 13. Doping concentrations of the compensation regions 15 may be in the same range as the doping concentration of the drift region 13. In a superjunction device, the doping concentration of the drift region 13 can be higher than in a non-superjunction transistor device and can be as high as 1E18 cm⁻³. In the vertical direction z of the semiconductor body 100, the compensation regions 15 may extend to the drain region 15, or may terminate spaced apart from the drain region 14 (not illustrated in FIG. 5).

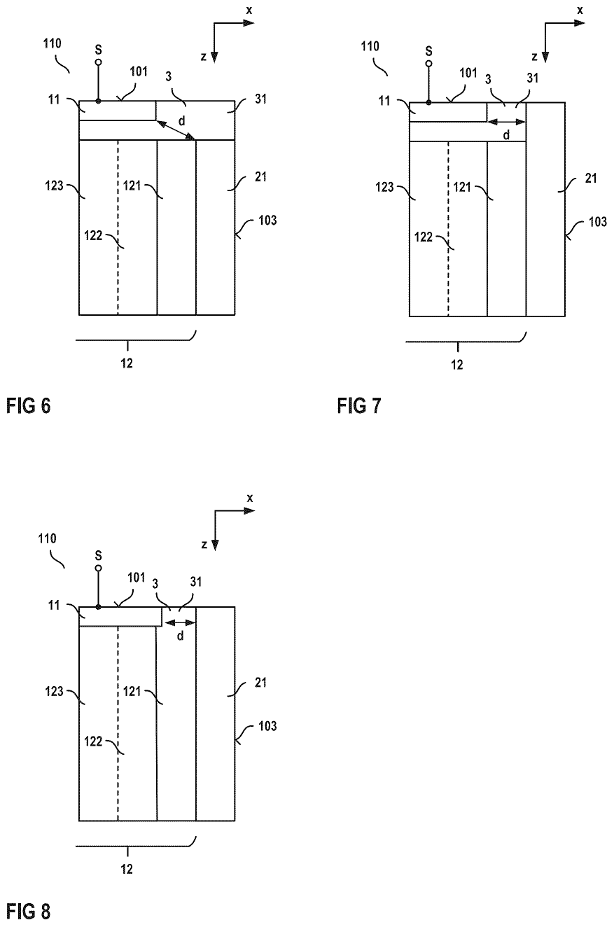

FIGS. 6-11 illustrate different examples for implementing the transition region 3. For this, each of FIGS. 6-11 illustrates a vertical cross-sectional view of one section of one mesa region 120, wherein the section illustrated includes a portion of the top surface 101 and a portion of one sidewall 103 of one mesa region 120.

Referring to the above, the transition region 3 is different from the source region 11 and the gate region 21. According to one example, the transition region 3 is a first doping type region 31 having a lower doping concentration than the source region 11. The first doping type region 31 is briefly referred to as first region 31 in the following. In this example, the doping concentration of the transition region 3 is different from the doping concentration of the source region 11 and at least the doping type of the transition region 3 is different from the doping type of the gate region 21. According to one example, the doping concentration of the first region 31 is less than a predefined first percentage of the doping concentration of the source region 11. According to one example, the first percentage is less than 10% (0.1), less than 1% (0.01), or less than 0.1% (0.001). As explained above, the doping concentration as used herein is the peak doping concentration, so that the peak doping concentration of the first region 31 may be less than the predefined first percentage of the peak doping concentration of the source region 11.

Different examples for implementing the transition region 3 as a first doping type region 31 are illustrated in FIGS. 6-8.

According to one example illustrated in FIG. 6, the transition region 3, in the lateral direction x, extends to the mesa sidewall 103, so that the gate region 21 adjoins the transition region 3 in the vertical direction z. Furthermore, the transition region 3 is arranged between the source region 11 and the channel region 12. It may be possible that the transition region 3 directly adjoins at least one of the source region 11 and the channel region 12. In some examples, the transition region 3 directly adjoins both the source region 11 and the channel region 12.

FIG. 7 illustrates a modification of the example illustrated in FIG. 6. In the example according to FIG. 7, the gate region 21, along the sidewall 103, extends to the top surface 101, so that the gate region 21 adjoins the transition region 3 in the lateral direction x.

In the examples illustrated in FIGS. 6 and 7, the transition region 3 has a doping concentration different from the doping concentration of the channel region 12. The transition region 3 may have a doping concentration that is higher than the doping concentration of the channel region 12 or lower than the doping concentration of the channel region 12. The latter includes that the doping concentration of the transition region 3 is higher or lower than the doping concentration of both the first region 121 and the second region 122 of the channel region 12.

Implementing the transition region 3 with a doping concentration different from the doping concentration of the channel region 12, however, is only an example. According to another example illustrated in FIG. 8, the transition region 3 formed between the source region 11 and the gate region 21 has the same doping concentration as the channel region 12. More specifically, in the example illustrated in FIG. 8, the transition region 3 has the same doping concentration as the first region 121 of the channel region 12.

According to another example, the transition region 3 is a second doping type region 32 having a lower doping concentration than the gate region 21. The second doping type region is briefly referred to as second region 32 in the following. In this example, the doping concentration of the transition region 3 is different from the doping concentration of the gate region 21 and at least the doping type of the transition region 3 is different from the doping type of the source region 11. According to one example, the doping concentration of the second region 32 is less than a predefined second percentage of the doping concentration of the gate region 21. According to one example, the second percentage is less than 50% (0.5), less than 33% (0.33), less than 20% (0.2), or even less than 10% (0.1). As explained above, the doping concentration as used herein is the peak doping concentration, so that the peak doping concentration of the second region 32 may be less than the predefined second percentage of the peak doping concentration of the gate region 21.

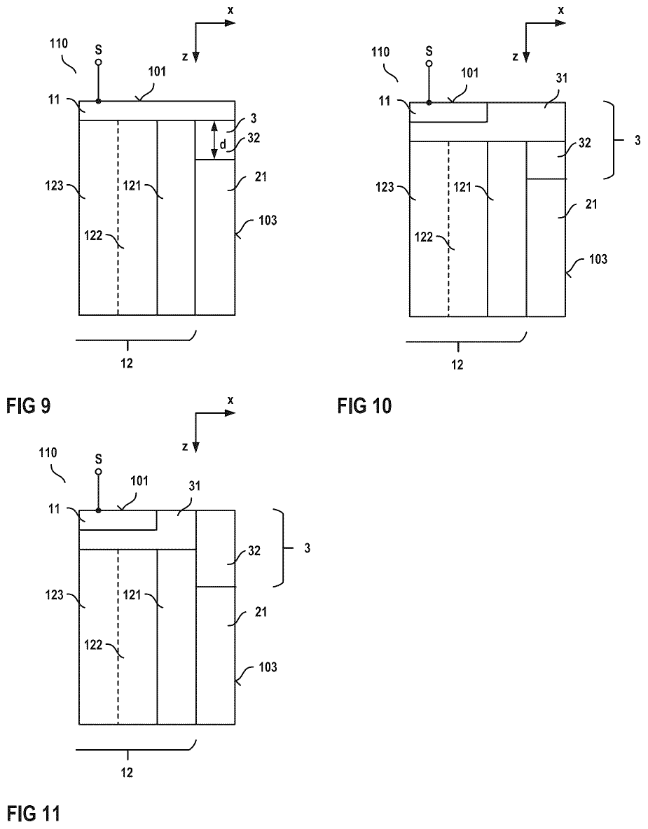

FIG. 9 illustrates one example in which the transition region 3 is a second region 32. In this example, the source region 11, in the lateral direction x extends to the sidewall 103. The transition region 3 adjoins the source region 11 in the vertical direction z, so that the transition region 3 is arranged between the source region 11 and the gate region 21 in the vertical direction z.

According to further examples illustrated in FIGS. 10 and 11, the transition region 3 includes a first region 31 and a second region 32. In each case, the first region 31 adjoins the source region 11 and the second region 32 adjoins the gate region 21. The first and second regions 31, 32 adjoin each other so that a PN junction is formed between the first and second regions 31, 32.

The example illustrated in FIG. 10 is a modification of the example illustrated in FIG. 6. In the example illustrated in FIG. 10, the first region 31 extends to the sidewall 103 in the lateral direction x and is arranged between the source region 11 and the channel region 12. The second region 32 is arranged between the first region 31 and the gate region 21 in the vertical direction z and adjoins the sidewall 103.

The example illustrated in FIG. 11 is a modification of the example illustrated in FIG. 7. In the example illustrated in FIG. 11, the second region 32 extends to the top surface 101 along the sidewall 103. The first region 31 is arranged between the second region 32 and the source region 11 in the lateral direction x. Furthermore, the first region 31 is arranged between the source region 11 and the channel region 12.

According to one example, in the examples illustrated in FIGS. 9 to 11, the second region 32 is restricted to the upper half of the mesa region 110. That is, a distance between a lower end of the second region 32 and the top surface 101 is less than 50% of the height h of the mesa region 110. The “lower end” of the second region 32 is the end of the second region 32 that faces away from the top surface 101.

Referring to the above, in the on-state of the transistor device, a current can flow between the drain and source nodes D, S via the drift region 13, the channel regions 12, and the source regions 11, wherein each channel region 12 is coupled to the respective source region 11.

The channel region 12 may directly be connected to the source region 11. That is, the channel region 12 may adjoin the source region 11. Examples for directly connecting the source region 11 to the channel region 12 are illustrated in FIGS. 8 and 9.

Alternatively, the channel region 12 is connected to the source region 11 via the first region 31 of the transition region 3. Examples for connecting the channel region 12 to the source region 11 via the first region 31 are illustrated in FIGS. 6-7 and 10-11.

According to one example, the transition region 3 is implemented such that a minimum distance d between the source region 11 and the gate region 21 is at least 100 nanometers (nm), at least 150 nm, or at least 200 nm. According to one example, the minimum distance is selected from between 100 nanometers and 500 nanometers. According to one example, the minimum distance d is less than 600 nanometers.

Independent of the specific way the transition region 3 is implemented, there is a PN junction on the path that runs along the shortest distance d between the source region 11 and the gate region 21. Thus the doping concentration of the source region 11 decreases from the peak doping concentration of the source region 11 as a start value along this path in the direction of the gate region 21. Equivalently, the doping concentration of the gate region 21 decreases from the peak doping concentration of the gate region 21 as a start value along this path in the direction of the source region 11.

According to one example, the shortest distance d between the source region 11 and the gate region 21 is the shortest distance between a first position at which the doping concentration of the source region 11 has decreased to the first percentage of the peak doping concentration of the source region 11 and a second position at which the doping concentration of the gate region 21 has decreased from the peak doping concentration to the second percentage of the doping concentration of the gate region 21. In other words, a border between the source region 11 and the transition region 3 is at the first position and a border between the gate region 21 and the transition region 3 is at the second position. Between the first and second positions, the transition region 3 has a doping concentration of the first doping type and lower than the first percentage of the peak doping concentration of the source region 11 and/or a doping concentration of the second doping type and lower than the second percentage of the peak doping concentration of the gate region 21.

According to another example, the distance between the source region 11 and the gate region 21 is less than 40% or less than 30% of the mesa width w.

A width of the source region 11, which is a dimension of the source region 11 in the lateral direction x, is less than 30%, less than 25% or less than 20%, for example. The width of the source region 11 is at least 10% of the mesa width w, for example.

According to one example, the source region 11 is essentially arranged in the center of the mesa region 110, so that a distance between the source region 11 and each of the two opposing sidewalls 103 is essentially the same. This, however, is only an example. It is also possible to implement the source region 11 such that the source region 11 is spaced apart from both sidewalls 103, but has different distances to the two opposing sidewalls 103.

The presence of the transition region 3 between the source region 11 and the gate region 21 is beneficial in view of reducing a leakage current of the transistor device. This is explained in the following.

For explanation purposes it is assumed that the transition region 3 is omitted, so that the source region 11 adjoins the gate region 21. Referring to the above, the gate region 21 may have a doping concentration higher than 1E18 cm⁻³ and the source region 11 may have a doping concentration higher than 1E19 cm⁻³. When the source region 11 adjoins the gate region 21, a PN junction is directly formed between the source region 11 and the gate region 21. In the region of the PN junction, the doping concentration changes from the first type doping concentration of the source region 11 to the second type doping concentration of the gate region 21. A dimension (length) of the region in which such change of the doping concentration takes place may range between several nanometers and several 10 nanometers, such as about 30 nanometers This is significantly shorter than the minimum distance d between the source region 11 and the gate region 21 in the presence of a transition region 3.

In the off-state of the transistor device, the PN junction between the source region 11 and the gate region 21 is reverse biased. Due to the high doping concentrations of the source region 11 on one side and the gate region 21 on the other side, reverse biasing the PN junction may cause so-called band-to-band-tunneling (BTBT), which is one source of a leakage current between the gate node G and the source node S in the off-state of the transistor device. Furthermore, forming the highly doped source and gate regions 11, 21 inevitably results in crystal damages in the crystal lattice of the semiconductor body 100. When the PN junction is reverse biased, a space charge region (depletion region) expands in the source and gate regions 11, 21 on both sides of the PN junction. Crystal damages that are located at positions covered by the depletion region may act as generation centers for generating charge carriers, so that such crystal damages are a further source of the leakage current between the gate node G and the source node S in the off-state.

In the transistor device explained herein before, in which the transistor cells 1 include the transition region 3, the change of the doping from the first doping type to the second doping type is softer or more smoothly compared to the situation without a transition region 3. Owing to this gradual change, less BTBT occurs. In addition, less generation of charge carriers due to crystal damages may occur close to the PN junction. Dependent on the implementation of the transition region 3, a PN junction is formed between the first region 31 and the gate region 21 (see, e.g., FIGS. 6-8), between the second regions 32 and the source region 11 (see, e.g., FIG. 9), or between the first and second regions 31, 32 (see, e.g., FIGS. 10-11). In each case, at least one of the two regions forming the PN junction has a doping concentration that is lower than the respective region in the hypothetical case in which the source region 11 adjoins the gate region 21, so that BTBT as well as charge carrier generation due to crystal damages is reduced. Furthermore, at a PN junction formed between doped regions having significantly different doping concentrations the space charge region mainly expands in the doped region having the lower doping concentration, so that crystal damages that may be present in the higher doped region may not be covered by the space charge region and are not effective in view of generating a leakage current.

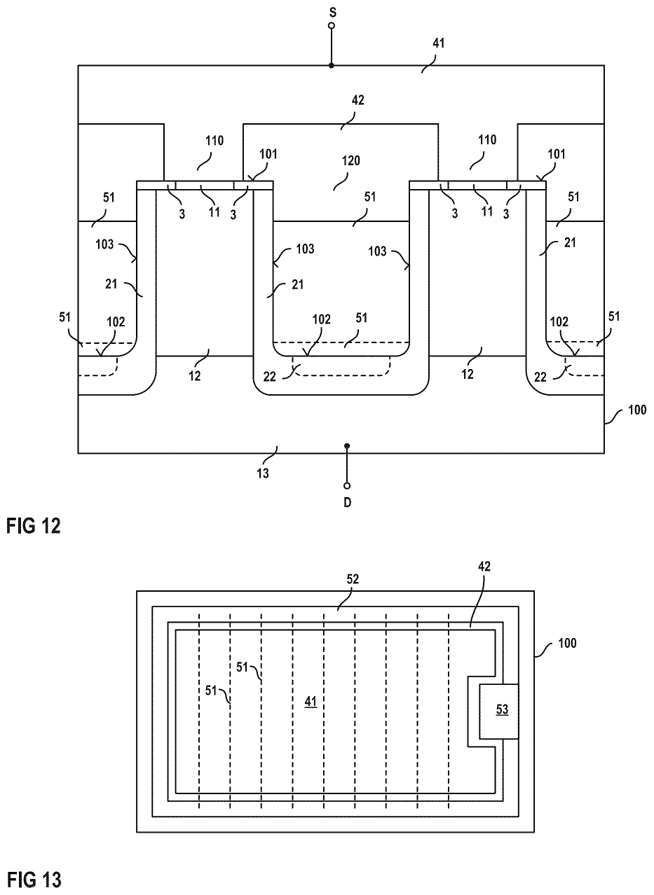

Referring to the above, the source regions 11 of the individual transistor cells 1 are connected to the source node S, and the gate regions 21 are connected to the gate node G. One example for connecting the source regions 11 to the source node S and the gate regions 21 to the gate node G is illustrated in FIG. 12.

FIG. 12 illustrates a vertical cross-sectional view of one section of the semiconductor body 100. In the example illustrated in FIG. 12, the source regions 11 of the transistor cells are connected to a source electrode (source metallization) 41 which forms the source node S or is connected to the source node S. The source electrode 41 is connected to each of the source nodes 11. The material of the source electrode 41 and the doping concentration of the source regions 11 are adapted to one another such that ohmic contacts are formed between the source electrode 41 and the source regions 11. Doping concentration of the source regions 11 higher than 1E19 cm⁻³, as explained above, are sufficient to achieve ohmic contacts. The source metallization 41 includes a metal, such as copper (Cu), titanium (Ti), aluminum (Al), nickel (Ni), an alloy, such as an alloy including two or more of copper (Cu), titanium (Ti), aluminum (Al), nickel (Ni), or the like. According to one example, the source metallization 41 includes a first layer of one electrically conducting material and contacting the source regions 11 and a second layer above the first layer. The second layer includes a material different from the first layer.

Referring to FIG. 12, the gate regions 21 are connected to gate electrodes 51 formed in the trenches 120. The gate electrodes 51 are connected to the gate node G, so that the gate regions 21 are connected to the gate node G via the gate electrodes 51. One example for connecting the gate electrodes 51 to the gate node G is illustrated in FIG. 13.

Each gate electrode 51 is formed in a respective trench 120 such that the gate electrode 51 at least covers portions of the sidewalls 103 and/or portions of the bottom 102 of the trench 120. In the example illustrated in FIG. 12, the gate electrode 51 covers both the bottom 102 and portions of the sidewalls 103 of the respective trench. This, however, is only an example.

According to another example illustrated in dashed lines in FIG. 12, the gate electrode 51 essentially only covers the bottom 102 of the respective trench 120 to connect the gate electrode 51 to the gate regions 21 formed below the bottom 102 and formed along the sidewalls 103 adjoining the respective trench bottom 102.

According to one example, the doping concentrations of the gate regions 21 are high enough to form and make contact between the gate regions 21 and the gate electrode 51. The gate electrodes 51 include a highly doped polycrystalline semiconductor material, such as polysilicon. According to another example, the gate electrodes 51 include a metal selected from the same group of metals as the source metallization 4 explained hereinabove. In this way, each of the gate electrodes 51 is electrically connected to the gate regions 21 adjoining the sidewalls 103 and the bottom 102 of the trench 120 in which the gate electrode 51 is formed.

The gate electrodes 51 are electrically insulated from the source metallization 41 by insulating layers 42 formed between the source metallization 41 and the gate electrodes 51.

FIG. 13 shows a top view of the transistor device according to any one of the examples explained herein before. More specifically, FIG. 13 shows a top view of the semiconductor body 100 with the source metallization 41. Examples of the gate electrodes 51 and their position below the source metallization 41 are illustrated in dashed lines in FIG. 13. In this example, the gate electrodes 51, below the source metallization 42, extend beyond the source metallization 42 and are connected to a gate runner 52. The gate runner 52 is formed above the insulating layer 42 and is connected to a gate pad 53. The gate pad 53 is connected to the gate node G or forms the gate node G of the transistor device.

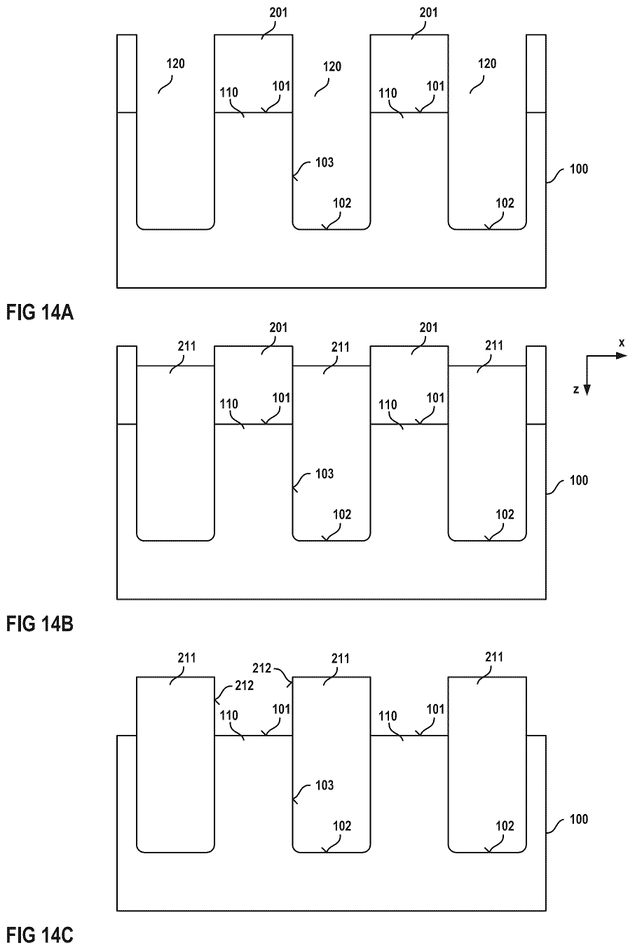

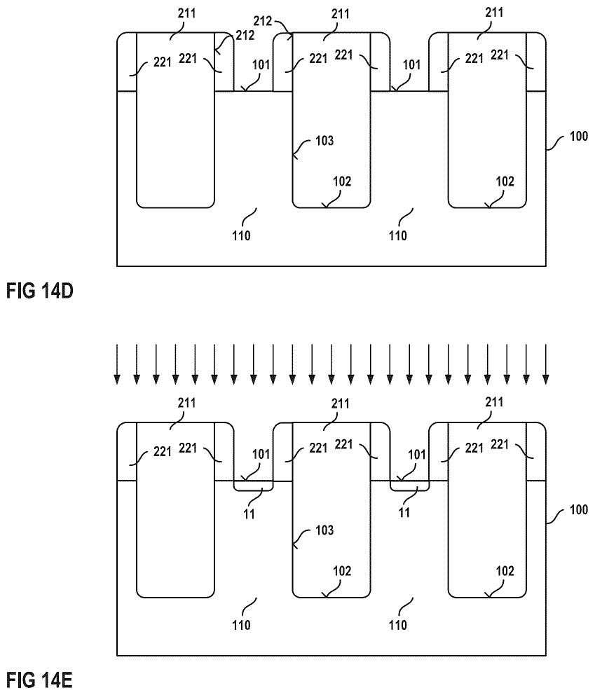

In some of the examples, such as the examples illustrated in FIGS. 6-8 and 10-11, explained herein before, the source region 11 is spaced apart from the sidewalls 103 of the mesa region 110 in which the source region 11 is formed. FIGS. 14A-14E illustrate one example of a self-aligned process for forming source regions 11 that are spaced apart from sidewalls 103 of the mesa regions 110. Each of FIGS. 14A-14E illustrates a vertical cross-sectional view of one section of the semiconductor body 100 at different stages of the manufacturing process.

FIG. 14A illustrates the semiconductor body 100 after forming the trenches 120 in the first surface 101. Forming the trenches 120 includes forming an etch mask 201 above the first surface 101. The etch mask 201 includes openings in which the surface 101 is not covered. Etching the trenches 120 includes etching the trenches 120 in the openings, that is, in those sections of the surface 101 not covered by the etch mask 201. The etch mask 201 is an oxide hard mask, for example. According to another example, the etch mask 201 includes a layer stack with layers of different materials, wherein one of these layers may be an oxide hard mask layer.

Referring to FIG. 14B, the method further includes forming sacrificial plugs 211 in the trenches 120 such that the sacrificial plugs 211 fill the trenches 120 and, in the vertical direction z, extend beyond the first surface 101, so that the sacrificial plugs 211 adjoin sidewalls of the openings of the etch mask 201. The material of the sacrificial plugs 211 is different from the material of the etch mask 201 and the material of the semiconductor body 100 in such a way that the sacrificial plugs 211 can be etched selectively relative to the material of the etch mask 201 and the material of the semiconductor body 100, while the material of the sacrificial plugs 211 is not damaged or only slightly damaged. The sacrificial plugs 211 may include a polycrystalline semiconductor material, such as polysilicon, for example.

Referring to FIG. 14C, the etch mask 201 is removed after forming the sacrificial plugs 211. As can be seen from FIG. 14B, sidewalls of the openings of the etch mask 21 are essentially aligned with sidewalls of the trenches 120 and, therefore, the sidewalls of the mesa regions 110 defined by the trenches 120. Consequently, after removing the etch mask 201, sidewalls 212 of the sacrificial plugs 211 that extend beyond the first surface 101 are essentially aligned with the sidewalls 103 of the mesa regions 110.

Referring to FIG. 14D, the method further includes forming spacers 221 on the sidewalls 212 of the sacrificial plugs 211. Forming the spacers 221 may include depositing a spacer layer above (e.g., on top of) the sacrificial plugs 211 and on the sidewalls 212 of the sacrificial plugs 211 and on the first surface 101 of the semiconductor body 100, and removing portions of the spacer layer in an anisotropic etching process, so that the spacers 221 remain on the sidewalls 212 of the sacrificial plugs. The spacer layer is an oxide layer, for example.

Referring to FIG. 14E, the method further includes an implantation process in which dopant atoms of the first doping type are implanted into those sections of the first surface 101 not covered by the spacers 221. In this way, source regions 11 are formed in the top surfaces 101 of the mesa regions 110 at positions that are spaced apart from the sidewalls 103 of the mesa regions 110. The distance between the source region 11 and the sidewalls 103 is defined by the dimensions of the spacers 221 in the lateral direction x. According to one example, dimensions of the spacers 221 in the lateral direction x are such that the source region 11 is formed at a position that is between 200 nm and 400 nm, in particular between 250 nm and 350 nm spaced apart from the sidewalls 103.

In addition to implanting dopant atoms of the first doping type, forming the source regions 11 may include a thermal process in which the implanted dopant atoms of the first doping type are activated.

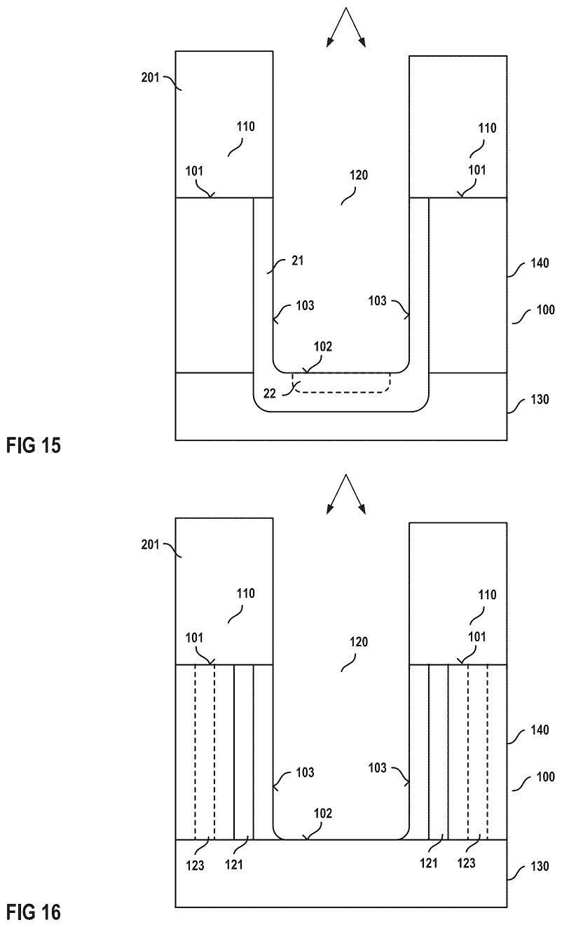

Examples for forming the gate regions 21 and the channel regions 12 are explained with reference to FIGS. 15 and 16 in the following. Each of FIGS. 15 and 16 illustrate a vertical cross-sectional view of one section of the semiconductor body 100 during the respective manufacturing process.

Referring to FIG. 15, forming the gate regions 21 along the bottom 102 and the sidewalls 103 of the trenches 120 includes implanting dopant atoms of the second doping type into the bottom 102 and the sidewalls 103. Different processes are possible for forming the gate regions 21 along the sidewalls 103 and along the bottom 102.

According to one example, only tilted implantation processes are used to form the gate regions 21. In this example, implantation angles are adjusted such that in a first tilted implantation process dopant atoms are implanted into one of the two opposing sidewalls 103 and the bottom 102, and in a second implantation process dopant atoms are implanted into the other one of the two opposing sidewalls 103 and the bottom 102. In this way, a higher dopant dose is implanted into the bottom 102, resulting in the more highly doped region 22.

In addition to implanting dopant atoms into the bottom 102 using two tilted implantation processes dopant atoms can be implanted into the bottom 102 using a non-tilted (vertical) implantation process.

According to another example, dopant atoms are implanted into the bottom 102 using a non-tilted implantation process, dopant atoms are implanted into one of the two opposing sidewalls using a first tilted implantation process, and dopant atoms are implanted into the other one of the two opposing sidewalls 103 using a second tilted implantation process. In this example, implantation angles in the first and second tilted implantation processes are adjusted such that dopant atoms are not implanted into the bottom 102 or are only implanted to a negligible extent.

In addition to implanting the second type dopant atoms, forming the gate regions 21 may include a thermal process in which the implanted dopant atoms are activated.

Referring to FIG. 15, an implantation mask may be formed above (e.g. on top of) the top surfaces 101 of the mesa regions 110 before the implantation process, wherein the implantation mask protects the top surfaces 101 from having dopant atoms implanted therein. According to one example, the etch mask 201 used for forming the trenches 120 is used as the implantation mask.

Referring to FIGS. 16, forming the channel region 12, in particular forming the first regions 121 of the channel regions 12, may include implanting dopant atoms of the first doping type into the sidewalls 103 of the trenches 120 using tilted implantation processes. According to one example, implantation angles in the implantation processes for forming the first regions 121 are selected such that dopant atoms are implanted into the sidewalls 103 and the top surface 101 but are not implanted into the bottom 102 or are only implanted into the bottom 102 to a negligible extent.

According to one example, implantation doses for forming the first regions 121 of the channel regions 12 are significantly lower than implantation doses for forming the gate regions 21. In this example, the implantation angles in the process for forming the first regions 121 do not necessarily have to be adjusted such that dopant atoms are not implanted into the bottom 102. This is because second type dopant atoms implanted into the bottom 102 for forming the gate regions 21 may heavily outweigh the first type dopant atoms implanted into the bottom 102 when forming the first regions 121, so that gate regions 21 having an effective doping concentration of the second doping type are formed along the trench bottoms 102.

In addition to implanting the first type dopant atoms, forming the first regions 121 may include a thermal process in which the implanted dopant atoms are activated.

Forming the optional third regions 123 may include a further tilted implantation process in which first type dopant atoms are implanted into the sidewalls 103 of the mesa regions 110. Optionally, an implantation mask, such as the etch mask 201, formed above (e.g., on top of) the top surfaces 101 of the mesa regions 110 protects the top surfaces 101 from having dopant atoms implanted therein.

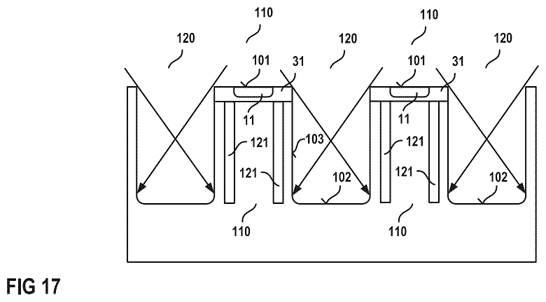

FIG. 17 illustrates one example of a method in which the same implantation processes are used for forming the transition regions 3 and the first regions 121 of the channel regions 12. Referring to FIG. 17, this method includes tilted implantation processes after removing the etch mask 201. The tilted implantation processes include at least two tilted implantation processes, wherein in each of these tilted implantation processes first type dopant atoms are implanted in a respective one of the sidewalls 103 of the mesa regions 110 and into the top surface 101, wherein dopant atoms implanted into the sidewalls 103 form the first regions 121 of the channel regions 12 and dopant atoms implanted into the top surface 101 form the transition regions 3, in particular the first regions 31 of the transition regions 3. According to one example, implantation angles in the two implantation processes are selected such that dopant atoms are not implanted into the bottom 100 or are implanted into the bottom 102 only to a negligible extent.

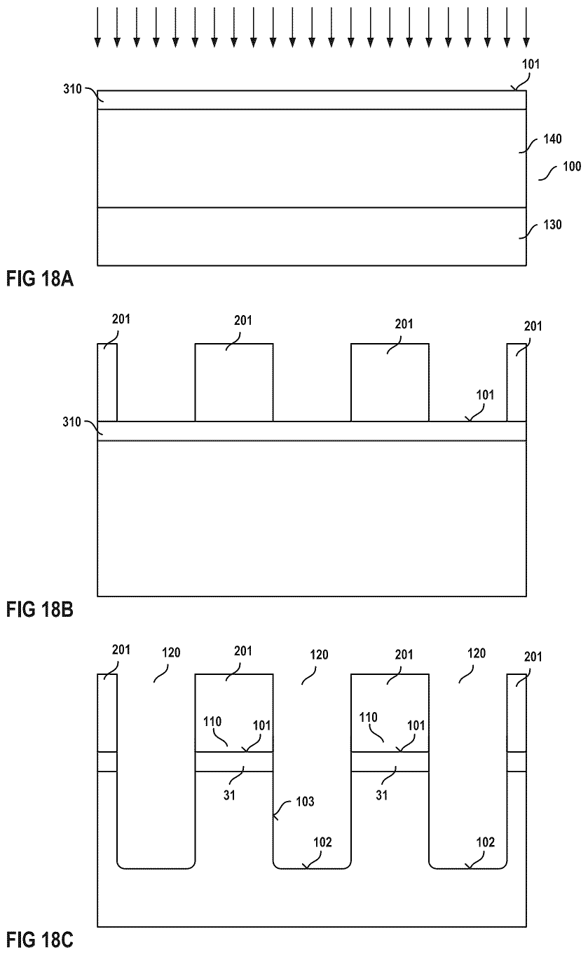

Another example for forming the transition regions, in particular first regions 31 of the transition regions, is illustrated in FIGS. 18A-18C. Each of these figures shows a vertical cross-sectional view of the semiconductor body 100 at different stages of the manufacturing process.

Referring to FIG. 18A, the method includes a blanket implantation in which first type dopant atoms are implanted into the first surface 101 of the first semiconductor body 100 in order to form a doped region 310 of the first doping type along the first surface 101. This implantation process takes place before forming the trenches 120.

Referring to FIGS. 18B-18C, forming the trenches 120 includes forming the etch mask 201 above the first surface 101 (see FIG. 18B), and etching the trenches using the etch mask 201 (see FIG. 18C). Those sections of the doped region 310 remaining after forming the trenches 120 form the first regions 31 of the gate-source drift regions 3. The source regions 11 may be formed using the process according to FIGS. 14A-14E after forming the transition regions 3.

Some of the processes explained herein before may have the effect that both dopant atoms of the first doping type and dopant atoms of the second doping type are implanted into the same region of the mesa region 110. Referring to the example illustrated in FIG. 15, forming the gate regions 21 may include implanting second type dopant atoms into the sidewalls 103. Furthermore, referring to the examples illustrated in FIGS. 17 and 18A-18C, forming the transition region 3 may include implanting first type dopant atoms into the top surface 101 of the mesa regions 110. Thus, combining the method according to FIG. 15 with one of the methods according to FIGS. 17 and 18A-18C results in a transition region 3 which, in a corner region of the mesa region 110, includes dopant atoms of the first doping type and dopant atoms of the second doping type. A “corner region” of the mesa region 110 is a region adjoining both the top surface 101 and one sidewall 103.

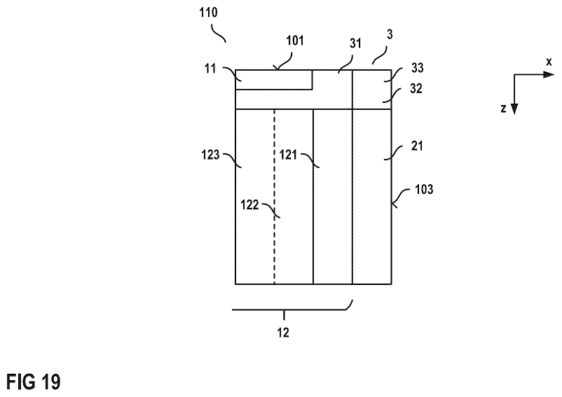

A transition region 3 resulting from a combination of the process according to FIG. 15 and one of the processes according to FIGS. 17 and 18A-18C is illustrated in FIG. 19 in greater detail. Referring to FIG. 19, the transition region 3 includes a first region 31, which results from implanting first type dopant atoms into the top surface 101 in one of the processes according to FIGS. 17 and 18A-18C, and a third region 33. The third region 33 is located in the corner region of the mesa region 110, adjoins the first region 31 and the gate region 21 and includes first type dopant atoms resulting from one of the processes according to FIGS. 17 and 18A-18C, and second type dopant atoms resulting from the process according to FIG. 15. The effective doping concentration of the third region 33 is either of the first doping type or the second doping type. According to one example, the third region 33 is of the second doping type. Due to the presence of the first doping type atoms in the third region 33 the effective doping concentration of the third region 33 is lower than the effective doping concentration of the adjoining gate regions 21. Thus, the third region 33 is a second region 32 of the type explained herein before, that is, a doped region of the second doping type and having a lower doping concentration than the gate region 21. The third region 33 is spaced apart from the source region 11 and is separated from the source region 11 by the first region 31 arranged between the source region 11 and the third region 33. Some aspects of the transistor device and the method explained hereinabove are briefly summarized in the following.

According to one example, the transistor device includes a semiconductor body with a plurality of mesa regions; and a plurality of transistor cells each formed in a respective one of the plurality of mesa regions. Each transistor cell includes a source region of a first doping type; a gate region of a second doping type complementary to the first doping type and spaced apart from the source region; a channel region of the first doping type; and a transition region different from the source region and the gate region. The transition region is arranged between the source region and the gate region and adjoins both the source region and the gate region.

The transition region may include a first region of the first doping type adjoining the source region, wherein a peak doping concentration of the first region is less than a first percentage of peak doping concentration of the source region. The first percentage is less than 10%, less than 1%, or less than 0.1%, for example. According to one example, the first region adjoins the gate region.

Additionally to the first region or alternatively to the first region, the transition region may include a second region of the second doping type adjoining the gate region, wherein a peak doping concentration of the second region is less than a second percentage of a peak doping concentration of the gate region. The first percentage is less than 50%, less than 33%, less than 20%, or less than 10%.

According to one example, the transition region is devoid of the first region, so that the second region adjoins the source region. According to another example, the transition region includes both the first region and the second region, wherein the second region adjoins the first region.

According to one example, a shortest distance between the source region and the gate region across the transition region is at least 100 nanometers, at least 150 nanometers, or at least 200 nanometers. The shortest distance between the source region and the gate region across the transition region may be the shortest distance between a first position in the source region at which the doping concentration equals the first percentage of the peak doping concentration of the source region and a second position in the gate region at which the doping concentration equals the second percentage of the peak doping concentration of the gate region.

The channel region may adjoin the gate region and be connected to the source region.

According to one example, the transistor device further includes a drift region of the first doping type adjoining the channel regions of the transistor cells. Furthermore, a drain region of the first doping type may adjoin the drift region and be separated from the channel regions of the transistor cells by the drift region.

A source electrode may be ohmically connected to the source regions of the transistor cells.

According to one example, the peak doping concentration of the source region is higher than 1E19 cm⁻³. According to one example, the peak doping concentration of the gate region is higher than 1E18 cm⁻³.

According to one example, the method includes forming trenches in a first surface of a semiconductor body, so that mesa regions of the semiconductor body are formed, each mesa region being located between neighboring trenches, wherein forming the trenches includes an etching process using an etch mask formed above the first surface. The method further includes forming sacrificial plugs in the trenches such that the sacrificial plugs fill the trenches and, in a vertical direction of the semiconductor, extend beyond the first surface, removing the etch mask, so that sidewalls of the sacrificial plugs are uncovered, forming spacers on the sidewalls of the sacrificial plugs, and forming source regions of a first doping type in the mesa regions. Forming the source regions includes implanting dopant atoms of the first doping type into the first surface using the sacrificial plugs and the spacers as an implantation mask.

The method may further include forming at least one gate region of a second doping type complementary to the doping type in each of the mesa regions. Forming the at least one gate region may include implanting dopant atoms of the second doping type via a sidewall of the respective mesa region into the respective mesa region before forming the sacrificial plugs.

Furthermore, the method may include forming at least one channel region of the first doping type in each of the mesa regions. Forming the at least one channel region may include implanting dopant atoms of the second doping type via a sidewall of the respective mesa region into the respective mesa region before forming the sacrificial plugs.

According to one example, the method further includes removing the sacrificial plugs, wherein forming the at least one channel region includes implanting dopant atoms of the first doping type via a sidewall of the respective mesa region into the respective mesa region after removing the sacrificial plugs.

Furthermore, at least one transition region may be formed in each of the mesa regions. According to one example, forming the at least one transition region includes forming a first region of the first doping type in the respective mesa region. Forming the first region may include implanting dopant atoms of the first to doping type via the first surface into the semiconductor body before forming the etch mask.

According to another example, the method further includes removing the sacrificial plugs, wherein forming the first region includes implanting dopant atoms of the first doping type via the first surface into the respective mesa region after removing the sacrificial plugs.

Forming the at least one channel region and the first region of the transition region may include forming the at least one channel region and the first region of the transition region using the same implantation processes.

What is claimed is:

1. A transistor device, comprising:
a semiconductor body comprising a plurality of mesa regions; and
a plurality of transistor cells each formed in a respective one of the plurality of mesa regions,
wherein each transistor cell comprises:
a source region of a first doping type;
a gate region of a second doping type complementary to the first doping type and spaced apart from the source region;
a channel region of the first doping type; and
a transition region different from the source region and the gate region,
wherein the transition region is arranged between the source region and the gate region and adjoins both the source region and the gate region.

2. The transistor device of claim 1, wherein the transition region comprises a first region of the first doping type adjoining the source region, and wherein a peak doping concentration of the first region is less than a percentage of a peak doping concentration of the source region.

3. The transistor device of claim 2, wherein the percentage is less than 10%, less than 1%, or less than 0.1%.

4. The transistor device of claim 2, wherein the first region further adjoins the gate region.

5. The transistor device of claim 1, wherein the transition region comprises a second region of the second doping type adjoining the gate region, and wherein a peak doping concentration of the second region is less than a percentage of a peak doping concentration of the gate region.

6. The transistor device of claim 5, wherein the percentage is less than 50%, less than 33%, less than 20%, or less than 10%.

7. The transistor device of claim 5, wherein the second region further adjoins the source region.

8. The transistor device of claim 1, wherein the transition region comprises a first region of the first doping type adjoining the source region and a second region of the second doping type adjoining the gate region, wherein the second region adjoins the first region, wherein a peak doping concentration of the first region is less than a first percentage of a peak doping concentration of the source region, and wherein a peak doping concentration of the second region is less than a second percentage of a peak doping concentration of the gate region.

9. The transistor device of claim 1, wherein a shortest distance between the source region and the gate region across the transition region is at least 100 nanometers, at least 150 nanometers, or at least 200 nanometers.

10. The transistor device of claim 9, wherein the shortest distance between the source region and the gate region across the transition region is the shortest distance between a first position in the source region at which the doping concentration equals a first percentage of a peak doping concentration of the source region and a second position in the gate region at which the doping concentration equals a second percentage of the peak doping concentration of the gate region.

11. The transistor device of claim 1, wherein the channel region adjoins the gate region and is connected to the source region.

12. The transistor device of claim 1, further comprising:
a drift region of the first doping type adjoining the channel regions of the transistor cells.

13. The transistor device of claim 12, further comprising:
a drain region of the first doping type adjoining the drift region and separated from the channel regions of the transistor cells by the drift region.

14. The transistor device of claim 1, further comprising:
a source electrode ohmically connected to the source regions of the transistor cells.

15. The transistor device of claim 1, wherein a peak doping concentration of the source region is higher than 1E19 cm⁻³.

16. The transistor device of claim 1, wherein a peak doping concentration of the gate region is higher than 1E18 cm⁻³.

17. A method, comprising:
forming trenches in a first surface of a semiconductor body, so that mesa regions of the semiconductor body are formed, each mesa region being located between neighboring trenches, wherein forming the trenches includes an etching process using an etch mask formed above the first surface;
forming sacrificial plugs in the trenches such that the sacrificial plugs fill the trenches and, in a vertical direction of the semiconductor body, extend beyond the first surface;
removing the etch mask, so that sidewalls of the sacrificial plugs are uncovered;
forming spacers on the sidewalls of the sacrificial plugs; and
forming source regions of a first doping type in the mesa regions,
wherein forming the source regions comprises implanting dopant atoms of the first doping type into the first surface using the sacrificial plugs and the spacers as an implantation mask.

18. The method of claim 17, further comprising:
forming at least one gate region of a second doping type complementary to the doping type in each of the mesa regions.

19. The method of claim 18, wherein forming the at least one gate region comprises implanting dopant atoms of the second doping type via a sidewall of the respective mesa region into the respective mesa region before forming the sacrificial plugs.

20. The method of claim 17, further comprising:
forming at least one channel region of the first doping type in each of the mesa regions.

21. The method of claim 20, wherein forming the at least one channel region comprises implanting dopant atoms of the second doping type via a sidewall of the respective mesa region into the respective mesa region before forming the sacrificial plugs.

22. The method of claim 20, further comprising:
removing the sacrificial plugs,
wherein forming the at least one channel region comprises implanting dopant atoms of the first doping type via a sidewall of the respective mesa region into the respective mesa region after removing the sacrificial plugs.

23. The method of claim 17, further comprising:
forming at least one transition region in each of the mesa regions.

24. The method of claim 23, wherein forming the at least one transition region comprises forming a first region of the first doping type in the respective mesa region.

25. The method of claim 24, wherein forming the first region comprises implanting dopant atoms of the first doping type via the first surface into the semiconductor body before forming the etch mask.

26. The method of claim 24, further comprising:
removing the sacrificial plugs,
wherein forming the first region comprises implanting dopant atoms of the first doping type via the first surface into the respective mesa region after removing the sacrificial plugs.

27. The method of claim 17, further comprising:
forming at least one channel region of the first doping type in each of the mesa regions;
forming a first region of a transition region of the first doping type in each of the mesa regions; and
removing the sacrificial plugs,
wherein the at least one channel region and the first region of the transition region are formed using a same implantation processes after removing the sacrificial plugs.
